(19) United States
(12) Patent Application Publication
(10) Pub. No.: US 2003/0119262 A1
(43) Pub. Date: Jun. 26, 2003

(54) Method for manufacturing non-volatile semiconductor memory device

(75) Inventor: Fumihiko Hayashi, Kawasaki (JP)

Correspondence Address: SUGHRUE MION, PLLC, 2100 PENNSYLVANIA AVENUE, N.W., WASHINGTON, DC, 20037, US

(73) Assignee: NEC ELECTRONICS CORPORATION

(21) Appl. No.: 10/323,922

(22) Filed: Dec. 20, 2002

(30) Foreign Application Priority Data
Dec. 20, 2001 (JP) 388408/2001

(51) Int. Cl. H01L 21/336

(52) U.S. Cl. 438/258; 438/264

(57) ABSTRACT

There is provided a provided method for manufacturing a non-volatile semiconductor memory device, wherein during a time when a silicon substrate is being annealed in an atmosphere containing N₂O or NO to perform the processing of nitriding on a tunnel oxide film in a memory cell portion peripheral circuit portion is covered with a mask which is made up of a multilayer structure of a masking poly-silicon film and a silicon oxide film and which has a masking action against nitrogen.

### BACKGROUND OF THE INVENTION

1. Field of the Invention

The present invention relates in general to a method for manufacturing a non-volatile semiconductor memory device and, more particularly to, the non-volatile semiconductor memory device manufacturing method which includes a processing of nitriding for improvement of a film quality of a tunnel insulation film.

The present application claims priority of Japanese Patent Application No. 2001-388408 filed on Dec. 20, 2001, which is hereby incorporated by reference.

2. Description of the Related Art

Semiconductor memory devices are roughly classified into a volatile semiconductor memory device in which information is erased when power is turned OFF and a non-volatile semiconductor memory device in which information is held even when power is turned OFF. The former is known as a Random Access Memory (RAM) and the latter, as a Read Only Memory (ROM).

The ROM, in particular, is applied by its feature of non-volatility to a variety of types of information processing apparatuses. Among the ROMS, there are widely used an Erasable and Programmable ROM (EPROM) which is capable of erasing once written information by application of an ultra-violet ray and then electrically writing information again and an Electrically Erasable and Programmable ROM (EEPROM) which is capable of electrically erasing once written information and then electrically writing information again. Furthermore, among the EEPROMS, there is known a Flash-EEPROM (F-EEPROM) which is capable of simultaneous erasure of information written already. The F-EEPROM is widely used because it can reduce a unit bit price greatly.

Non-volatile semiconductor memory devices including the F-EEPROM have a Metal-Oxide-Semiconductor (MOS) type construction having a stacked structure in which the device has a floating gate formed on a gate insulation film on the surface of a semiconductor substrate and a control gate formed on the floating gate via an insulation film.

The gate insulation film of the non-volatile semiconductor memory device is made up of a tunnel insulation film having such a small film thickness as to barely flow a tunnel current referred to as an F-N (Fowler-Nordheim) current on the semiconductor substrate surface below the floating gate.

In this configuration, by supplying a tunnel current from the semiconductor substrate through this tunnel insulation film to the floating gate, electrons are accumulated therein to store (write) information. Information erasure, on the other hand, is effected by supplying a tunnel current from the floating gate through the tunnel insulation film to the semiconductor substrate to thereby draw out the electrons from the floating gate. In such a manner, a threshold voltage of the MOS transistor varies with whether electrons are accumulated in the floating gate or not, so that information can be read out by detecting a variation in the threshold voltage.

Besides the above-described example of effecting F-N write-in/F-N erasure all through a channel, there have been proposed such a channel hot-electron type of a device as to perform a write-in operation by accelerating a channel current using a drain electric field and a gate electric field to inject electrons into the floating gate and such a type of a device as to effect information erasure by drawing electrons from the floating gate into a source or drain diffusion layer.

Performance of the non-volatile semiconductor memory device described above may be decided by a major criterion of, for example, the number of times of rewriting information. This number of rewriting times is known to vary with a film quality of a tunnel insulation film. In addition, it is traditionally known that the film quality of the tunnel insulation film can be improved effectively by nitriding the tunnel insulation film. For example, in the literature “Extended Abstracts of the 1994 International Conference on Solid State devices and Materials, pp. 859-861, Yokohama, 1994” describes a method for manufacturing an F-EEPROM having a tunnel insulation film made of an oxide/nitride film formed by using nitrogen oxide (N₂O) and performing process of nitriding.

The following will describe a conventional method for manufacturing a non-volatile semiconductor memory device along steps thereof with reference to FIGS. 7A-7C and FIGS. 8D-8F.

First, as shown in FIG. 7A, using a silicon substrate 51 and utilizing a known Local Oxidation of Silicon (LOCOS) or shallow Trench Isolation (STI) technology, a field oxide film 52 made of silicon oxide (SiO₂) is formed and then active regions 53 and 54 are formed in a memory cell formation-expected region (memory cell portion A) and a peripheral circuit formation expected region (peripheral circuit portion B) respectively. In the active region 53 is there formed a MOS transistor having the above-mentioned gate-stacked structure as a memory cell, while in the active region 54 is there formed a MOS transistor as a peripheral transistor which controls operations of the memory cell.

Next, the silicon substrate 51 is oxidized thermally to simultaneously form tunnel oxide films 55 and 56 made of a silicon oxide film respectively on surfaces of the active regions 53 and 54. Note here that tunnel oxide films 55 and 56 required for the memory cells in the memory cell portion A is different in thickness from a gate oxide film (described later) required for the MOS transistors in the peripheral circuit portion B, so that after the tunnel oxide films 55 and 56 are formed to the film thickness required for the memory cells in the memory cell portion A by this step, the gate oxide film once formed by this step is reformed by a following step so as to have the film thickness required for the MOS transistors in the peripheral circuit.

Next, as shown in FIG. 7B, a processing of nitriding is performed through a processing of annealing the silicon substrate 51 in an atmosphere containing nitrogen oxide, such as N₂O, NO or a like, to introduce nitrogen into the tunnel oxide films 55 and 56, thus forming nitride layers 55A and 56A respectively. By performing such a processing of nitriding, a film quality of especially the tunnel oxide film 55 in the memory cell portion A is improved.

Next, as shown in FIG. 7C, as a preparatory step for forming a floating gate (not shown) in the memory cell portion A, a poly-silicon film 57 is formed throughout the surface by Chemical Vapor deposition (CVD).

Next, as shown in FIG. 8D, only the poly-silicon film 57 in the memory cell portion A is patterned into a desired shape using a known photolithographic technology, thus forming a floating gate 58. In this case, the poly-silicon film 57 in the peripheral circuit portion B is left non-patterned. Next, using CVD, a silicon oxide film, a silicon nitride film, and another silicon oxide film are stacked in this order throughout the surface, thus forming a so-called ONO film 59.

Next, as shown in FIG. 8E, after only the memory cell portion A is covered by a photo-resist film 60, the photo-resist film 60 is used as a mask to etch the ONO film 59, the poly-silicon film 57, and the tunnel oxide film 56 in the exposed peripheral circuit portion B in this order, thus exposing the active region 54.

Next, as shown in FIG. 8F, after the photo-resist film 60 is removed in the peripheral circuit portion B, the silicon substrate 51 is oxidized thermally to newly form a gate oxide film 61 made of a silicon oxide film and having a desired film thickness, in order to form a MOS transistor on the surface of the active region 54 in the peripheral circuit portion B. In this thermal oxidation, since the ONO film 59 acts as an oxidation resistant film, the memory cell portion A is not oxidized, so that the tunnel oxide film 55 already formed is left as it is.

This conventional method for manufacturing a non-volatile semiconductor memory device, however, has a problem that in the etching step shown in FIG. 8E of exposing the active region 54 by etching the ONO film 59, the poly-silicon film 57, and the tunnel oxide film 56 in this order in the peripheral circuit portion B, the nitride layer 56A formed on the surface of the active region 54 in the peripheral circuit portion B in the processing of nitriding step of FIG. 7B may not completely be removed in some cases. In such a case, therefore, when the gate oxide film 61 is formed in the thermal oxidation step of FIG. 8F, a residual nitride film 56A has such an effect that the gate oxide film 61 may be formed thinner partially. This results in deterioration in insulation resistance of the gate insulation film 61, hence in reliability of a MOS transistor (not shown) which is formed in the peripheral circuit portion B. In addition, if the etching processing is prolonged in order to remove the residual nitride film 56A completely, the film thickness of the field oxide film 52 is decreased around the active region 54, thus deteriorating the element isolation resistance of the field oxide film 52. Furthermore, if the field oxide film 52 is formed especially by the STI technology, prolonged etching causes a silicon material in the active region 54 to have a sharp shape at an element isolation end. To this sharp portion, an electric field is concentrated, thus deteriorating the insulation resistance of the gate oxide film 61.

A method of manufacturing a non-volatile semiconductor memory device capable of avoiding an influence of the nitride layer which is formed by the above-mentioned processing of nitriding and left as non-removed in a region other than the memory cell portion A is disclosed in, for example, Japanese Patent Application Laid-open No. 2000-294659. This non-volatile semiconductor memory device manufacturing method is explained below along its steps with reference to FIGS. 9A to 9D.

First, as shown in FIG. 9A, an element isolation region (field oxide film) 72 is formed on a P-type silicon substrate 71 by utilizing a known LOCOS technology. Then, by injecting ions of an N-type impurity into an active region 73 on the left side in the figure (region expected to become the memory cell portion A) adjacent to the element isolation region 72, an N-type impurity region 75 is formed.

Next, as shown in FIG. 9B, the P-type silicon substrate 71 is oxidized thermally to form a first gate oxide film 76 on the surface of the surfaces of the active region 73 on the left side in the same figure and an active region 74 (region expected to become the peripheral circuit portion B) on the right side in the same figure. Next, the first gate oxide film 76 on the N-type impurity region 75 is partially etched to form a window portion 77 through which the N-type impurity region 75 is exposed. Then, in this window portion 77, a tunnel oxide film 78 is newly formed by thermal oxidation.

Next, the P-type silicon substrate 71 is subjected to a rapid lamp-heat processing of nitriding in an ammonia atmosphere to perform the processing of nitriding on the tunnel oxide film 78. Then, a first layer poly-silicon electrode 79 is formed on the first gate oxide film 76 and the tunnel oxide film 78. By the processing of nitriding, nitride layers 73A and 74A are formed on the surfaces of the active regions 73 and 74 respectively.

Next, as shown in FIG. 9C, the first gate oxide film 76 present on the active region 74 is removed by etching, Then, the P-type silicon substrate 71 is dipped into an aqueous solution containing ammonia (NH₃) and a hydrogen peroxide (H₂O₂) solution to thereby remove the nitride layer 74A formed under the first gate oxide film 76, thus exposing the active region 74.

Next, as shown in FIG. 9D, the P-type silicon substrate 71 is oxidized thermally to newly form a second gate oxide film 80 made of a silicon oxide film and having a desired film thickness on the surface of the active region 74. At the same time, an IPO (Inter Poly Oxide) film 81 is formed on the first layer poly-silicon electrode 79 in the active region 73. Then, a second layer poly-silicon electrode 82 is formed on the second gate oxide film 80 and the IFO film 81. Subsequently, elements necessary for the peripheral circuit portion B are formed in the active region through desired steps.

The conventional non-volatile semiconductor memory device manufacturing method described in Japanese Patent Application Laid-open No. 2000-294659, however, has a problem that a nitride layer formed in the processing of nitriding is left non-removed yet in the regions other than the memory cell portion A.

That is, almost as in the case of the conventional non-volatile semiconductor memory device manufacturing method described with reference to FIGS. 7A to 7C and FIGS. 8D to 8F, by the conventional non-volatile semiconductor memory device manufacturing method described in Japanese Patent Application Laid-open No. 2000-294659, prior to newly forming the second gate oxide film 80 in the active region 74 in the step of FIG. 9D, the step of FIG. 9C attempts to etch off the nitride layer 74A formed by the processing of nitriding. As described above, however, it is difficult to remove the nitride layer 74A completely, so that the nitride layer 74A is left non-removed inevitably.

### SUMMARY OF THE INVENTION

In view of the above, the present invention has been developed, and it is an object of the present invention to provide a non-volatile semiconductor memory device manufacturing method which can avoid deterioration in insulation resistance of a gate insulation film and deterioration in element isolation resistance of a field insulation film of a peripheral transistor in a peripheral circuit portion even if a processing of nitriding is performed in order to improve a film quality of a tunnel insulation film in a memory cell portion.

According to a first aspect of the present invention, there is provided a method for manufacturing a non-volatile semiconductor memory device including,

on a semiconductor substrate, a memory cell portion which stores information and a peripheral circuit portion which controls an operation of the memory cell portion, the method comprising the steps of:

forming a tunnel insulation film on a surface of the semiconductor substrate in the memory cell portion and then performing a processing of nitriding on the tunnel insulation film, covering the peripheral circuit portion with a masking means having a masking action against nitrogen.

In the foregoing, a preferable mode is one that wherein includes the method for manufacturing a non-volatile semiconductor memory device, wherein a nitride formed by the processing of nitriding on the masking means is removed at the same time as removing the masking means.

Also, a preferable mode is one that wherein includes the method for manufacturing a non-volatile semiconductor memory device, wherein after the masking means is removed, a gate insulation film for a peripheral transistor is formed on the surface of the semiconductor substrate in the peripheral circuit portion.

In the foregoing, a preferable mode is one that wherein includes the method for manufacturing a non-volatile semiconductor memory device, wherein the masking means is made up of a stacked structure containing a masking material having the masking action against the nitrogen.

In the foregoing, a preferable mode is one that wherein includes the method for manufacturing a non-volatile semiconductor memory device, wherein the masking means is made up of a stacked structure of a poly-silicon film and an oxide film.

In the foregoing, a preferable mode is one that wherein includes the method for manufacturing a non-volatile semiconductor memory device, wherein the masking means is made up of a nitride film.

According to a second aspect of the present invention, there is provided a method for manufacturing a non-volatile semiconductor memory device including, on a semiconductor substrate, a memory cell portion, which stores information and a peripheral circuit portion which controls an operation of the memory cell portion, the method comprising the steps of:

separating the semiconductor substrate into the memory cell portion and the peripheral circuit portion by an element isolation region and then sequentially forming a sacrificial insulation film and a masking material having a masking action against nitrogen in each of the memory cell portion and the peripheral circuit portion;

removing the masking material and the sacrificial insulation film only in the memory cell portion to expose a surface of the semiconductor substrate and then forming a tunnel insulation film on the surface of the semiconductor substrate;

performing annealing processing on the semiconductor substrate in an atmosphere containing at least nitrogen to perform a processing of nitriding on the tunnel insulation film; and

removing a nitride formed by the processing of nitriding on the masking material in the peripheral circuit portion at the same time as the masking material to thereby expose the surface of the semiconductor substrate and then forming a gate insulation film for a peripheral transistor on the surface of the semiconductor substrate.

In the foregoing, a preferable mode is one that wherein includes the method for manufacturing a non-volatile semiconductor memory device, wherein the step of performing the processing of nitriding on the tunnel insulation film is followed by a step of forming a conductive film in the memory cell portion and the peripheral circuit portion and then patterning the conductive film to thereby form a floating gate in the memory cell portion.

In the foregoing, a preferable mode is one that wherein includes the method for manufacturing a non-volatile semiconductor memory device, wherein the step of forming the floating gate is followed by a step of forming an inter poly oxide film at least on the floating gate.

With the above configurations, during a time when the silicon substrate is being annealed in an atmosphere containing at least nitrogen to perform the processing of nitriding on the tunnel oxide film in the memory cell portion, the peripheral circuit portion is covered by the masking means which has a masking action against nitrogen to prevent it from reaching the surface of semiconductor substrate in the peripheral circuit portion, so that no nitride layer is formed in the peripheral circuit portion, thus eliminating a residual nitride layer.

Therefore, even when the nitriding process is performed to improve the film quality of the tunnel insulation film in the memory cell portion it is possible to avoid deterioration in insulation resistance of the gate insulation film and deterioration in element isolation resistance of the field insulation film of the peripheral transistors in the peripheral circuit portion.

### BRIEF DESCRIPTION OF THE DRAWINGS

The above and other objects, advantages, and features of the present invention will be more apparent from the following description taken in conjunction with the accompanying drawings, in which:

FIGS. 1A-1C are process diagrams for sequentially showing a method for manufacturing a non-volatile semiconductor memory device according to a first embodiment of the present invention;

FIGS. 2D-2F are further process diagrams for sequentially showing the method of manufacturing the non-volatile semiconductor memory device according to the first embodiment;

FIGS. 3G-3H are still further process diagrams for sequentially showing the method of manufacturing the non-volatile semiconductor memory device according to the first embodiment;

FIGS. 4A-4C are process,diagrams for sequentially showing a method for manufacturing a non-volatile semiconductor memory device according to a second Embodiment of the present invention along steps;

FIGS. 5D-5F are further process diagrams for sequentially showing the method of manufacturing the non-volatile semiconductor memory device according to the second embodiment;

FIGS. 6G-6H are still further process diagrams for sequentially showing the method of manufacturing the non-volatile semiconductor memory device according to the second embodiment;

FIGS. 7A-7C are process diagrams for sequentially showing a configuration of a conventional method for manufacturing a non-volatile semiconductor memory device;

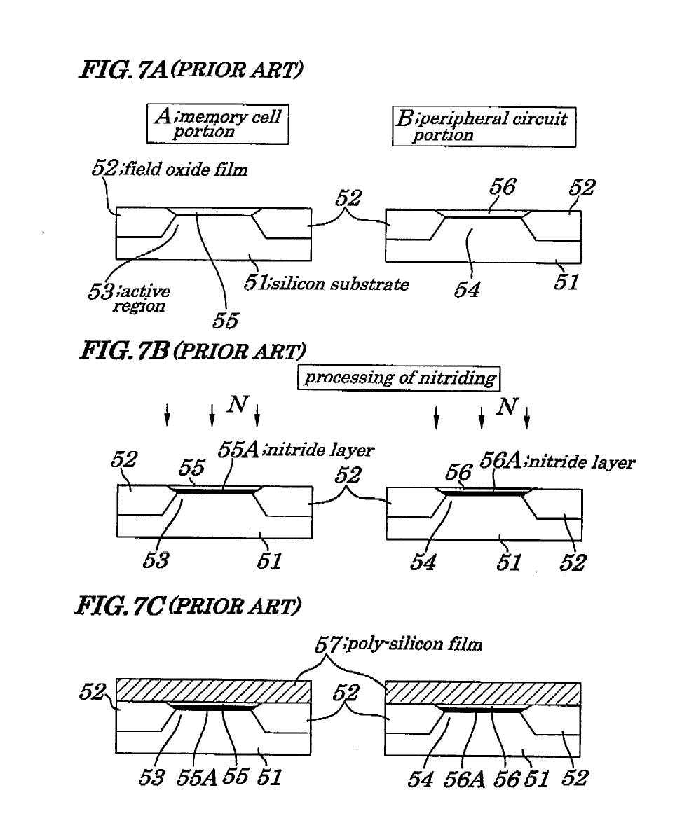

FIGS. 8D-8F are further process diagrams for sequentially showing the conventional method for manufacturing a non-volatile semiconductor memory device; and

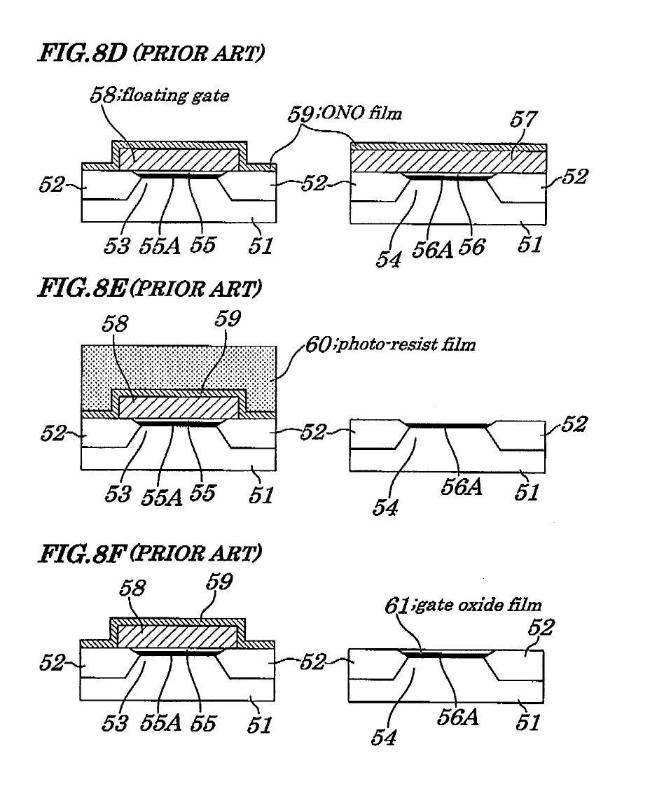

FIGS. 9A-9D are process diagrams for sequentially showing a configuration of another conventional method for manufacturing a non-volatile semiconductor memory device.

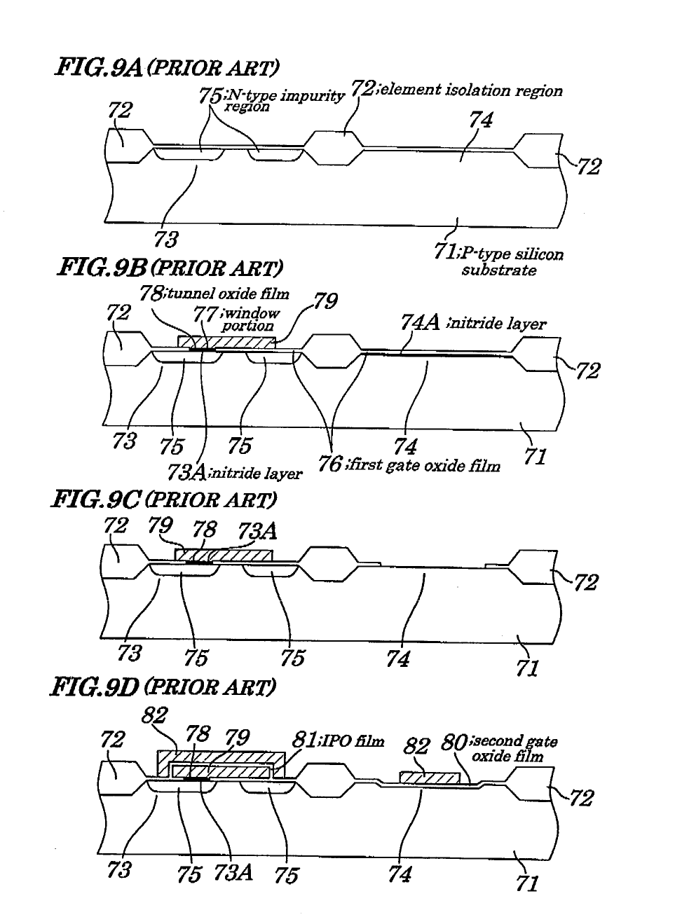

### DESCRIPTION OF THE PREFERRED EMBODIMENTS

Best mode of carrying out the present invention will be described in further detail using various embodiments with reference to the accompanying drawings. The description is made specifically using the embodiments.

### First Embodiment

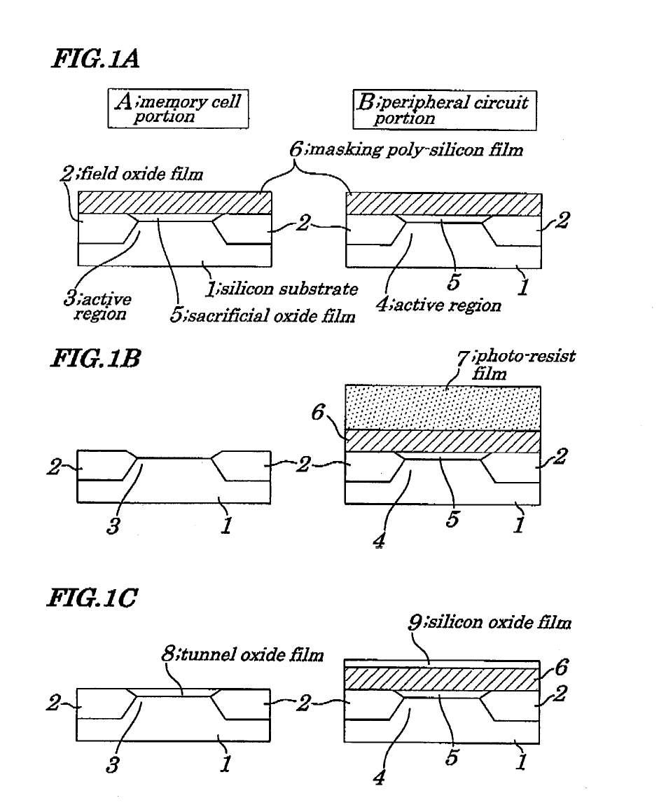

The following will describe a non-volatile semiconductor memory device manufacturing method according to the present embodiment along steps thereof with reference to FIGS. 1A to 1C, FIGS. 2D to 2F and FIGS. 3G and 3H.

First, as shown in FIG. 1A, using a silicon substrate 1 and utilizing a known Local Oxidation of Silicon (LOCOS) or Shallow Trench Isolation (STI) technology, a field oxide film 2 (element isolation region) made of a silicon oxide film is formed and then active regions 3 and 4 are formed in a memory cell formation-expected region (memory cell portion A) and a peripheral circuit formation-expected region (peripheral circuit portion B) respectively. Then, the silicon substrate 1 is oxidized thermally in an oxidizing atmosphere at 800-1000° C., to form a sacrificial oxide film 5 made of a silicon oxide film and having a film thickness of 10-30 nm on the surface of each of the active regions 3 and 4. Then, a masking poly-silicon film 6 having a film thickness of 50-200 nm is formed throughout the surface using CVD.

Next, as shown in FIG. 1B, only the peripheral circuit portion B is covered by a photo-resist film 7. Then, using this photo-resist film 7 as a mask, the masking poly-silicon film 6 and the sacrificial oxide film 5 in the memory cell portion A are etched in this order by dry etching, wet etching, or a like to expose the active region 3.

Next, as shown in FIG. 1C, after the photo-resist film 7 is removed, the silicon substrate 1 is oxidized thermally in an oxidizing atmosphere at 800-1000° C., to simultaneously form a tunnel oxide film 8 made of a silicon oxide film and having a film thickness of 8-15 nm on the surface of the active region 3 and a silicon oxide film 9 having a film thickness of 12-23 nm on the surface of the masking poly-silicon film 6 above the active region 4.

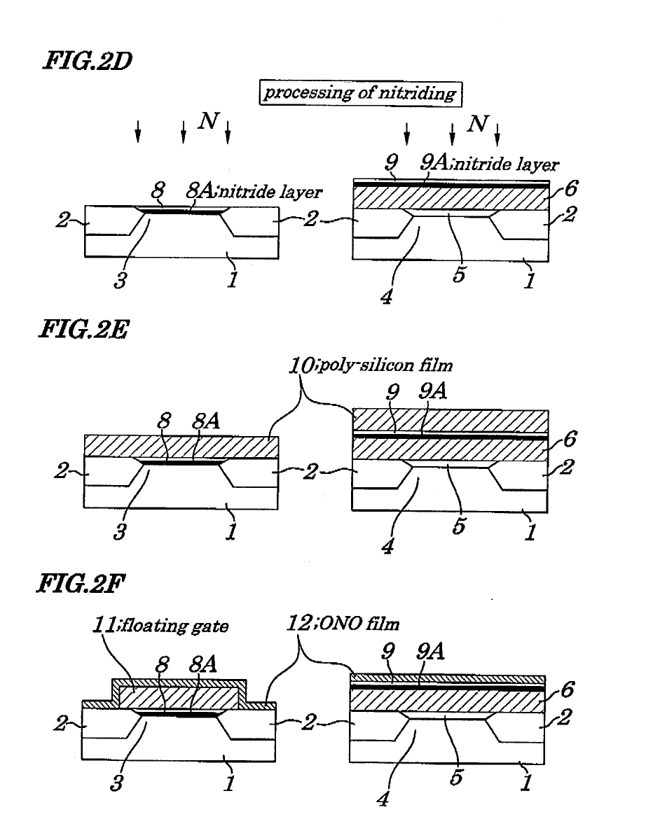

Next, as shown in FIG. 2D, the silicon substrate 1 is subjected to annealing processing in an atmosphere containing N₂O or NO at 1000-1100° C. for 1-10 minutes to introduce nitrogen into the tunnel oxide film 8 and the silicon oxide film 9, thus forming a nitride layers 8A and 9A respectively. By performing such a processing of nitriding, film quality of the tunnel oxide film 8 especially in the memory cell portion A is improved. During the processing of nitriding of this step, a stack structure made up of the masking poly-silicon film 6 and the silicon oxide film 9 in the peripheral circuit portion B acts as a masking material (masking means) having a masking action against nitrogen, so that the nitrogen does not reach the surface of the active region 4.

Next, as shown in FIG. 2E, as a preparatory step for forming a floating gate in the memory cell portion A, a poly-silicon film 10 having a film thickness of 100-300 nm is formed throughout the surface using CVD.

Next, as shown in FIG. 2F, only the poly-silicon film 10 in the memory cell portion A is patterned into a desired shape by a known photolithographic technology to form the floating gate 11, while on the other hand the poly-silicon film 10 in the peripheral circuit portion B is removed by using dry etching method, wet etching method, or the like. Then, a silicon oxide film having a film thickness of 4-10 nm, a silicon nitride film having a film thickness of 4-10 nm, and another silicon oxide film having a film thickness of 4-10 nm are stacked in this order throughout the surface using CVD, thus forming an ONO film 12 having a film thickness of 12-30 nm. This ONO film 12 acts as an IPO film such as described above.

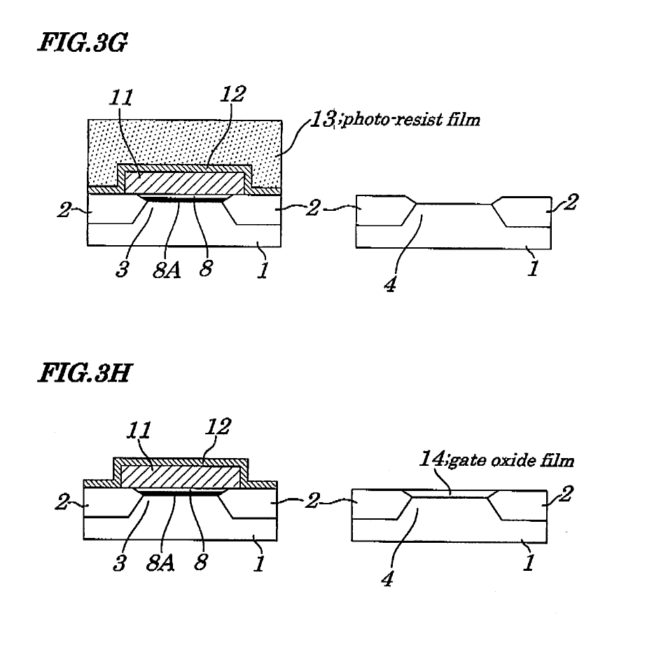

Next, as shown in FIG. 3G, only the memory cell portion A is covered by a photo-resist film 13. Then, using this photo-resist film 13 as a mask, unnecessary ONO film 12, silicon oxide film 9, nitride layer 9A, masking poly-silicon film 6, and sacrificial oxide film 5 in the peripheral circuit portion B are etched in this order by dry etching, wet etching, or the like, to expose the active region 4.

Next, as shown in FIG. 3H, after the photo-resist film 13 is removed, the silicon substrate 1 is oxidized thermally in an oxidizing atmosphere at 800-1000° C. to newly form a gate oxide film 14 made of a silicon oxide film and having a desired film thickness on the surface of the active region 4 in the peripheral circuit portion B. In this thermal oxidation, the ONO film 12 acts as an oxidation resistant film to prevent the memory cell portion A from being oxidized, so that the tunnel oxide film 8 already formed remains as it is.

Subsequently, desired steps are performed sequentially to form memory cells in the memory cell portion A and MOS transistors as a peripheral transistor in the peripheral circuit portion B, thus completing a non-volatile semiconductor memory device.

In such a manner, according to the non-volatile semiconductor memory device manufacturing method of this embodiment, in the step of FIG. 2D, during a time when the silicon substrate 1 is being annealed in an atmosphere containing N₂O or NO to perform the processing of nitriding on the tunnel oxide film 8 in the memory cell portion A, the peripheral circuit portion B is covered by the masking means which is made up of the stack structure of the masking poly-silicon film 6 and the silicon oxide film 9 and so has a masking action against nitrogen. Therefore, the nitrogen does not reach the active region 4, so that no nitride layer is formed in the active region 4, thus eliminating a residual nitride layer.

It is, therefore, possible to avoid deterioration in insulation resistance of the gate insulation film and deterioration in element isolation resistance of the field insulation film of the peripheral transistor in the peripheral circuit portion B even if a processing of nitriding is performed in order to improve the film quality of the tunnel insulation film in a memory cell portion A.

### SECOND EMBODIMENT

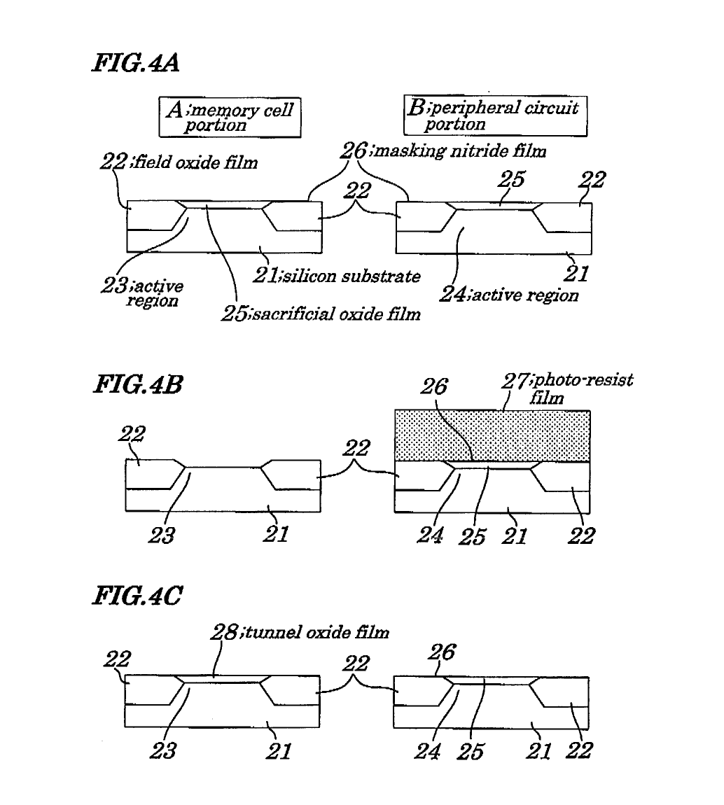

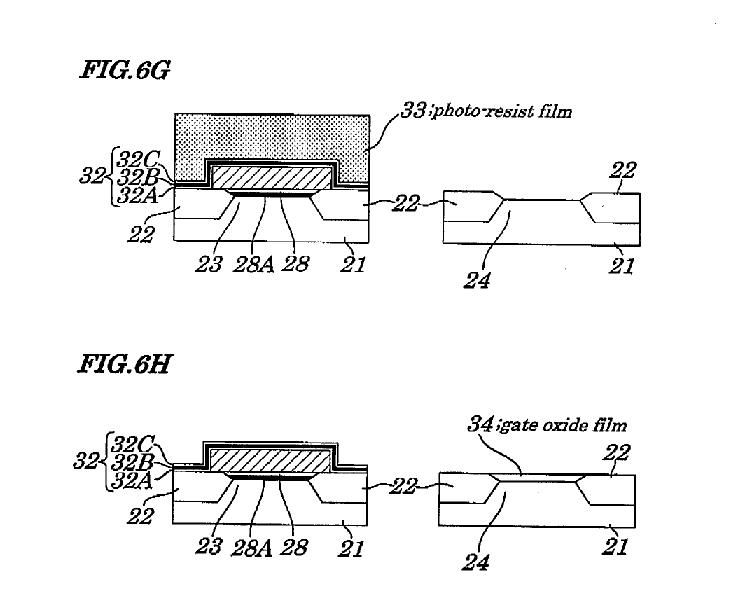

A non-volatile semiconductor memory device manufacturing method by the present embodiment greatly differs in configuration from that by the above-mentioned first embodiment in a respect that it uses a masking material different from that used in the processing of nitriding a tunnel oxide film 28 in a memory cell portion A. The following will describe the non-volatile semiconductor memory device manufacturing method of the present embodiment along steps thereof with reference to FIGS. 4A to 4C, FIGS. SD to 5F and FIGS. 6G and 6H.

First, as shown in FIG. 4A, using a silicon substrate 21 and utilizing a known Local Oxidation of Silicon (LOCOS) or Shallow Trench Isolation (STI) technology, a field oxide film 22 (element isolation region A) made of a silicon oxide film is formed and then active regions 23 and 24 are formed in a memory cell formation-expected region (memory cell portion A B) and a peripheral circuit formation-expected region (peripheral circuit portion B) respectively. Then, the silicon substrate 21 is oxidized thermally in an oxidizing atmosphere at 800-1000° C., to form a sacrificial oxide film 25 made of a silicon oxide film and having a film thickness of 10-30 nm on the surfaces of the active regions 23 and 24. Then, a masking nitride film 26 having a film thickness of 4-20 nm is formed throughout the surface using CVD.

Next, as shown in FIG. 4B, only the peripheral circuit portion B is covered by a photo-resist film 27. Then, using this photo-resist film 27 as a mask, the masking nitride film 26 and the sacrificial oxide film 25 in the memory cell portion A are etched in this order by dry etching, wet etching, or a like to expose the active region 23.

Next, as shown in FIG. 4C, after the photo-resist film 27 is removed, the silicon substrate 21 is oxidized thermally in an oxidizing atmosphere at 800-1000° C., to form a tunnel oxide film 28 made of a silicon oxide film and having a film thickness of 8-15 nm only on the surface of the active region 23. During this thermal oxidation, on the surface of the active region 24 there is present the masking nitride film 26 acting as an oxidation resistant mask, so that no silicon oxide film is formed thereon.

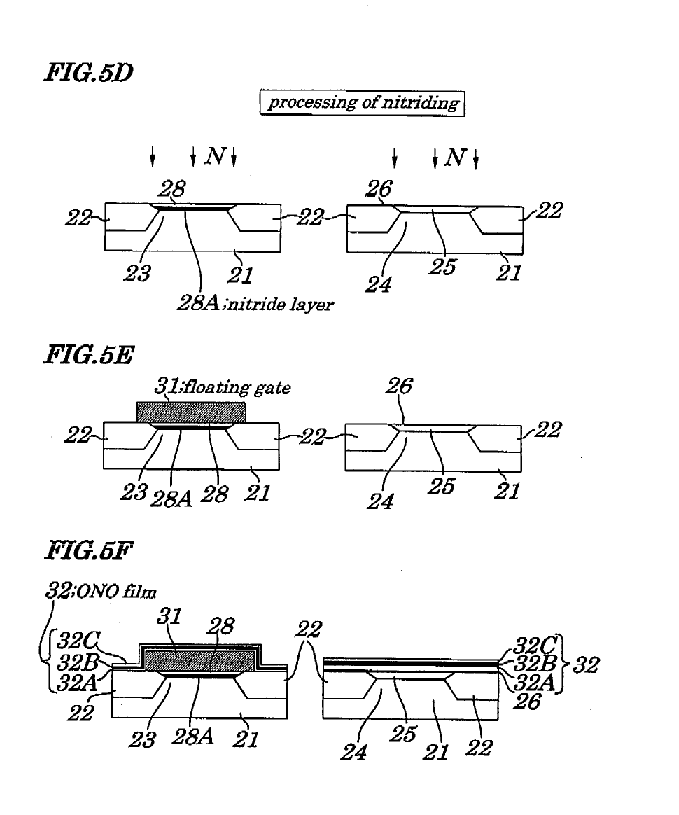

Next, as shown in FIG. 5D, the silicon substrate 21 is subjected to annealing processing in an atmosphere containing N₂O or NO at 1000-1100° C. for 1-10 minutes to introduce nitrogen into the tunnel oxide film 28, thus forming a nitride layer 28A. By performing such a processing of nitriding, film quality of the tunnel oxide film 28 especially in the memory cell portion A is improved. At the processing of nitriding in this step, no nitride layer 28A is formed because in the peripheral circuit portion B is there present the masking nitride film 26 which acts as a masking material having a masking action against nitrogen.

Next, as shown in FIG. 5E, a poly-silicon film having a film thickness of 100-300 nm is formed throughout the surface using CVD. Then, only the poly-silicon film present in the memory cell portion A is patterned into a desired shape by a known photolithographic technology to thereby form a floating gate 31, while on the other hand the poly-silicon film present in the peripheral circuit portion B is etched off by dry etching, wet etching, or the like.

Next, as shown in FIG. 5F, a silicon oxide film 32A having a film thickness of 4-10 nm, a silicon nitride film 32B having a film thickness of 4-10 nm, and a silicon oxide film 32C having a film thickness of 4-10 nm are stacked in this order throughout the surface using CVD, thus forming an ONO film 32 having a film thickness of 12-30 nm. This ONO film 32 acts as an IPO film such as described above.

Next, as shown in FIG. 6G, only the memory cell portion A is covered by a photo-resist film 33. Then, using this photo-resist film 33 as amask, unnecessary ONO film 32 and masking nitride film 26 in the peripheral circuit portion B are etched in this order by dry etching to expose the active region 24.

Especially according to this embodiment using the masking nitride film 26 as a masking material in the processing of nitriding, by employing dry etching in this etching step, etching can be performed through various gas systems which can be switched in the same recipe, so that the ONO film 32 and the masking nitride film 26 can be etched consecutively. This etching step, therefore, can be simplified as compared to the first embodiment.

Next, as shown in FIG. 6H, after the photo-resist film 33 is removed, the silicon substrate 21 is oxidized thermally in an oxidizing atmosphere at 800-1000° C. to newly form a gate oxide film 34 made of a silicon oxide film and having a desired film thickness on the surface of the active region 24 in the peripheral circuit portion B. In this thermal oxidation, the ONO film 32 acts as an oxidation resistant film to prevent the memory cell portion A from being oxidized, so that the tunnel oxide film 28 already formed remains non-removed.

Subsequently, desired steps are performed sequentially to form memory cells in the memory cell portion A and MOS transistors as peripheral transistors in the peripheral circuit portion B, thus completing a non-volatile semiconductor memory device.

Thus, a configuration of the present embodiment also provides almost the same effects as those described in explanation of the first embodiment.

In addition, the configuration of the present embodiment makes it possible to etch the unnecessary insulation films in the peripheral circuit portion B simply.

It is apparent that the present invention is not limited to the above embodiments but may be changed and modified without departing from the scope and spirit of the invention. For example, any type of non-volatile semiconductor memory device can be applied to the EEPROMS in general as far as it has a tunnel insulation film 28 in the memory cell portion A. Furthermore, the gate insulation film employed may be a nitride film or a double-film structure of oxide and nitride films. That is, besides a MOS transistor, a Metal Nitride Semiconductor (MNS) or a Metal Nitride Oxide Semiconductor (MNOS) transistor may be employed as far as it is of a Metal Insulator Semiconductor (MIS) type. Furthermore, although the film thicknesses, materials, and forming conditions of various insulation films and conductive films have been described in one example, they may be changed in accordance with applications, purposes, or a like.

Still furthermore, the step of forming the floating gate 11, 31 may be followed by a step of forming an inter poly oxide film at least on the floating gate 11, 31.

What is claimed is:

1. A method for manufacturing a non-volatile semiconductor memory device comprising a semiconductor substrate, a memory cell portion formed on said semiconductor substrate and storing information, and a peripheral circuit portion formed on said semiconductor substrate and controlling an operation of said memory cell portion, said method comprising the steps of:
forming a tunnel insulation film on a surface of said semiconductor substrate in said memory cell portion and then performing a processing of nitriding on said tunnel insulation film, covering said peripheral circuit portion with a mask having a masking action against nitrogen.

2. The method according to claim 1, wherein a nitride formed by said processing of nitriding on said mask is removed at the same time as removing said mask.

3. The method according to claim 2, wherein after said mask is removed, a gate insulation film for a peripheral transistor is formed on said surface of said semiconductor substrate in said peripheral circuit portion.

4. The method according to claim 1, wherein said mask is made up of a multilayer structure containing a masking material having said masking action against said nitrogen.

5. The method according to claim 4, wherein said mask is made up of a multilayer structure of a poly-silicon film and an oxide film.

6. The method according to claim 1, wherein said mask is made up of a nitride film.

7. A method for manufacturing a non-volatile semiconductor memory device comprised of, on a semiconductor substrate, a memory cell portion which stores information and a peripheral circuit portion which controls an operation of said memory cell portion, said method comprising the steps of:
separating said semiconductor substrate into said memory cell portion and said peripheral circuit portion by an element isolation region and then sequentially forming a sacrificial insulation film and a masking material having a masking action against nitrogen in each of said memory cell portion and said peripheral circuit portion;
removing said masking material and said sacrificial insulation film only in said memory cell portion to expose a surface of said semiconductor substrate and then forming a tunnel insulation film on said surface of said semiconductor substrate;
performing annealing processing on said semiconductor substrate in an atmosphere containing at least nitrogen to perform a processing of nitriding on said tunnel insulation film; and
removing a nitride formed by said processing of nitriding on said masking material in said peripheral circuit portion at the same time as said masking material to thereby expose said surface of said semiconductor substrate and then forming a gate insulation film for a peripheral transistor on said surface of said semiconductor substrate.

8. The method according to claim 7, wherein said step of performing said processing of nitriding on said tunnel insulation film is followed by a step of forming a conductive film in said memory cell portion and said peripheral circuit portion and then patterning said conductive film to thereby form a floating gate in said memory cell portion.

9. The method according to claim 8, wherein said step of forming said floating gate is followed by a step of forming an inter poly oxide film at least on said floating gate.

10. The method according to claim 7, wherein said mask material is made up of a nitride film.
